(19) United States
(12) Patent Application Publication
(10) Pub. No.: US 2017/0161404 A1
(43) Pub. Date: Jun. 8, 2017

(54) INTERIOR DECORATING SYSTEM USING THREE-DIMENSIONAL AND OTHER PROPERTIES OF A SPACE

(71) Applicant: Wal-Mart Stores, Inc., Bentonville, AR (US)

(72) Inventors: Donald R. High, Noel, MO (US); Michael D. Atchley, Springdale, AR (US); David C. Winkle, Bella Vista, AR (US)

(21) Appl. No.: 15/367,894

(22) Filed: Dec. 2, 2016

Related U.S. Application Data
(60) Provisional application No. 62/263,499, filed on Dec. 4, 2015.

(51) Int. Cl. G06F 17/50

(52) U.S. Cl. CPC G06F 17/5004; G06F 17/5009

(57) ABSTRACT

A scan of a space is performed to obtain a three-dimensional model. Design choices of a user are received such as color palette, style, design philosophy and the like. Other factors affecting design may also be received such as children, pets, and work schedule. Environmental factors (sun, exterior temperature) and properties (thermal, acoustic, lighting) of the space may also be measured. Product records are analyzed according to size compatibility with the scanned space as well as compatibility with the environmental factors, properties, user design choices, and user lifestyle characteristics. Products are selected based on compatibility and user choice and are added to the model to obtain a combined model that is rendered for the user or three-dimensionally printed.

### CROSS-REFERENCE TO RELATED APPLICATION

This application claims the benefit of U.S. Provisional Application No. 62/263,449 , filed Dec. 4, 2015 , which is incorporated herein by reference in its entirety.

### BACKGROUND

Field of the Invention

This invention relates to systems and methods for facilitating interior design choices and visualizing modifications to a space.

Background of the Invention

Interior decorating tastes are unique to the individual. Even an individual with definite tastes may not truly understand how a space will look until all design elements are present. Tools exist to, for example, superimpose images of products or change the color of paint on a room. However, these tools are still unable to enable the accurate visualization of a space.

The systems and methods disclosed herein provide an improved approach for visualizing design choices in a space as well as facilitating the making of appropriate design choices.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a schematic block diagram of a network environment suitable for implementing embodiments of the invention;

FIG. 2 is a schematic block diagram of an example computing device suitable for implementing methods in accordance with embodiments of the invention;

FIG. 3 is a process flow diagram of a method for performing measurements of a space in accordance with an embodiment of the invention;

FIG. 4 is a process flow diagram of a method for facilitating design choices in accordance with an embodiment of the present invention;

FIG. 5 is a process flow diagram of a method for identifying products for a space in accordance with an embodiment of the present invention; and

FIGS. 6A and 6B are isometric views of a space illustrating features that may be detected from a 3D model of a space.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

Embodiments in accordance with the present invention may be embodied as an apparatus, method, or computer program product. Accordingly, the present invention may take the form of an entirely hardware embodiment, an entirely software embodiment (including firmware, resident software, micro-code, etc.), or an embodiment combining software and hardware aspects that may all generally be referred to herein as a “module” or “system.” Furthermore, the present invention may take the form of a computer program product embodied in any tangible medium of expression having computer-usable program code embodied in the medium.

Any combination of one or more computer-usable or computer-readable media may be utilized. For example, a computer-readable medium may include one or more of a portable computer diskette, a hard disk, a random access memory (RAM) device, a read-only memory (ROM) device, an erasable programmable read-only memory (EEPROM or Flash memory) device, a portable compact disc read-only memory (CD-ROM), an optical storage device, and a magnetic storage device. In selected embodiments, a computer-readable medium may comprise any non-transitory medium that can contain, store, communicate, propagate, or transport the program for use by or in connection with the instruction execution system, apparatus, or device.

Computer program code for carrying out operations of the present invention may be written in any combination of one or more programming languages, including an object-oriented programming language such as Java, Smalltalk, C++, or the like and conventional procedural programming languages, such as the “C” programming language or similar programming languages. The program code may execute entirely on a computer system as a stand-alone software package, on a stand-alone hardware unit, partly on a remote computer spaced some distance from the computer, or entirely on a remote computer or server. In the latter scenario, the remote computer may be connected to the computer through any type of network, including a local area network (LAN) or a wide area network (WAN), or the connection may be made to an external computer (for example, through the Internet using an Internet Service Provider).

The present invention is described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions or code. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a non-transitory computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

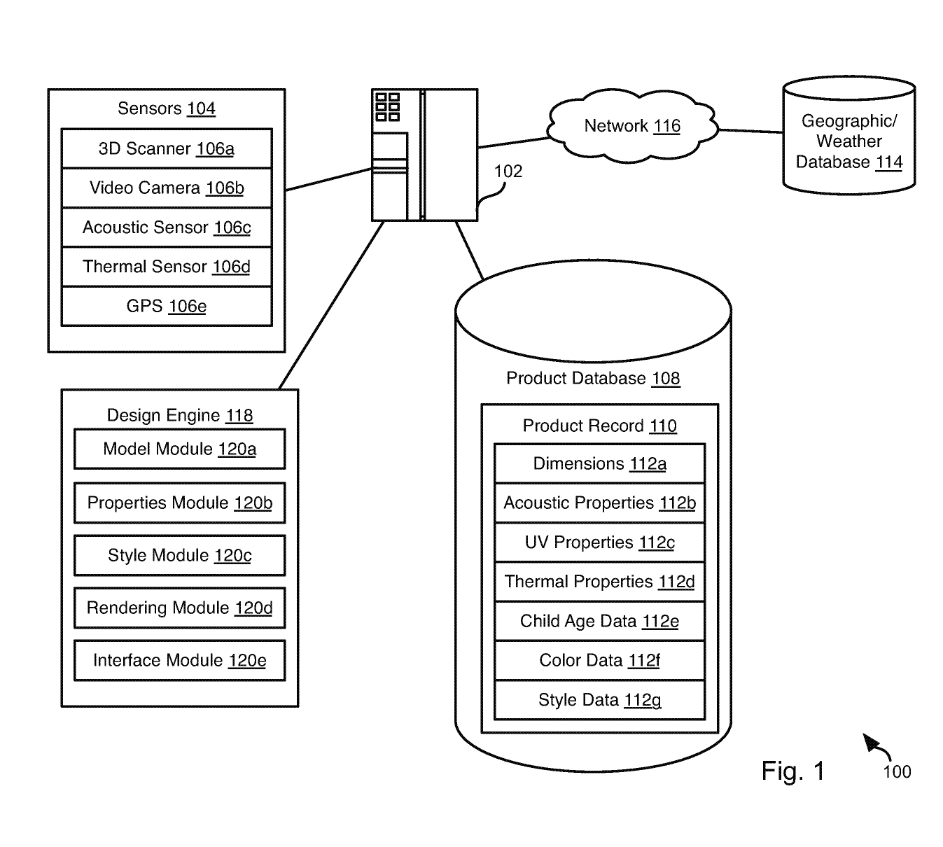

Referring to FIG. 1, a network environment 100 for implementing the systems and methods disclosed herein may include some or all of the illustrated components. As described in greater detail herein. The environment 100 may be used to facilitate the making of design choices and to enable the visualization of design choices in an existing space. To that end, the server system 102 may receive data from one or more sensors 104.

The sensors 104 may include one or more three-dimensional (3D) scanners 106a. The scanners 106a may include any three dimensional scanner known in the art. For example, the scanners 106a may include the FARO FOCUS 3D laser scanner or other type of laser scanner. The scanners 106 may include an optical scanner such as the FARO FREESTYLE3D SCANNER or some other optical 3D scanner known in the art. In some embodiments, the 3D scanner 106a may be mounted to an unmanned aerial vehicle (e.g. quadcopter or other drone) that is programmed to fly with the scanner around an interior or exterior space in order to perform a scan.

The sensors 104 may include a video camera 106b. In some embodiments, a field of view of the 3D scanner 106a may be simultaneously captured with the video camera 106b during scanning. The image data from the video camera may then be overlaid on a point cloud obtained from the scanner 106a to obtain a full color model of the area scanned. The manner in which the point cloud and image data are combined may include any technique known in the art.

The sensors 104 may include an acoustic sensor 106c. In particular, the acoustic sensor 106c may include any combination of speakers and microphones known in the art for use in characterizing the acoustic properties of a space.

The sensors 104 may include a thermal sensor 106d. The thermal sensor may be a simple thermometer or an infrared camera. Thermal images of a space may be captured using the thermal sensor 106d to characterize variation of temperature within a space, identify potential areas of thermal heat loss or heat gain, and otherwise determine areas of a space that affect the thermal properties thereof.

The sensors 104 may include one or more sensors to determine the position and orientation of a room such as a GPS receiver 106e. Other positioning sensors such as a magnetic compass may also be used to determine the position and orientation of a space.

The server system 102 may select products and treatments from a product database 108 as potential design elements for a space. The product database 108 may include a plurality of product records 110 for a plurality of products or treatments available from one or more retailers.

The product record 110 may include some or all of the illustrated data fields 112a-112g. Not all data fields 112a-112g will be relevant to all products and therefore may be omitted as needed. The product record 110 may include dimensions 112a of a product, e.g. the height, width, and depth of the product. The dimensions 112a may include a three-dimensional model of the product.

Acoustic properties 112b indicate the ability of a product to absorb sound waves. For example, some products may appreciably muffle or dampen echoes in a space. For example, acoustic properties 112b may include an absorption coefficient that indicates a ratio of reflected sound energy from the product to incident sound energy on the product. Likewise, a measure of the area, or effective area of a product, that performs sound absorption in a space may be recorded in the acoustic properties 112b.

The product record 110 may include ultraviolet (UV) properties 112c. The UV properties 112c indicate how well the product withstands UV light. For example, a product that will fade or degrade if constantly exposed to UV light from a window may have a lower rating in the UV properties 112c than a product that is treated or inherently possesses the ability to avoid degradation when exposed to UV light.

The product record 110 may include thermal properties 112d. Products such as curtains, carpeting, and the like may have insulative properties. This product may be recorded in the thermal properties 112d as the “R-value” conventionally used to characterize insulation.

The product record 110 may include child age data 112e that indicates an age appropriateness for the product. For some articles this may be a metric of one or more of how breakable the product is, how easy to clean a product is, whether the product has small parts, and other factors that may make a product suitable or unsuitable for use in a home with children of a particular age. The child age data 112e may be expressed in terms of an age range (e.g. 3+, 5+) of children in the presence of which the product can be used.

The product record 110 may include color data 112f. The color data 112f may indicate the color or colors of the product and may include a listing of multiple colors or color combinations in which the product is available. The color data 112f may be expressed as RGB (red green blue) values or using other codified representation of colors. The color data 112f may indicate other visual properties of the product such as translucence, reflectivity (matte vs. shiny), and the like.

The product record 110 may include style data 112g. The style data may include one or more keywords indicating the style to which the product corresponds or of which the product may be part, such as “modern,” “industrial,” “southwestern,” and the like.

The server system may access one or more public databases 114 to obtain information such as weather information for a particular location and geographic information regarding a space's location and orientation. The information may be obtained over a network 116 such as the Internet or other type of network connection.

The server system 102 may host or access a design engine 118. The design engine 118 may include a model module 120a. The model module 120a may generate a model from a point cloud from a 3D scanner 106a and image data from the camera 106b. The model module 102a may combine these to define a full color model of a room that has been scanned. The model module 120a may perform a filtering function, i.e. cleaning up of a model to remove extraneous objects resulting from the scanning and removing objects in the scan.

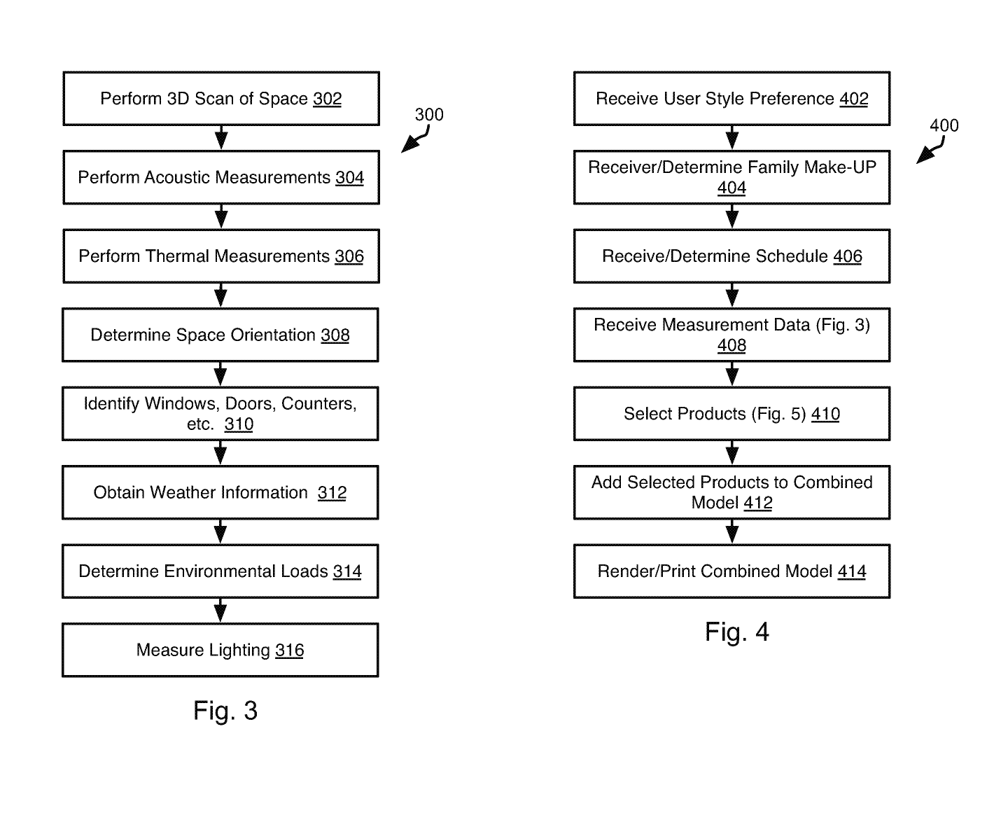

The design engine 118 may include a properties module 120b. The properties module 120b may collect other data to characterize a space such as acoustic, thermal, and lighting properties. The operation of the model and properties modules 120a, 120b is described below with respect to FIG. 3.

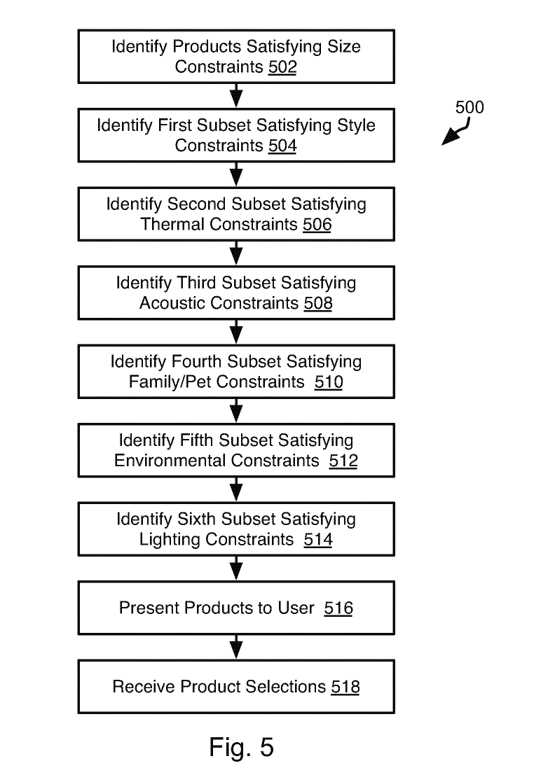

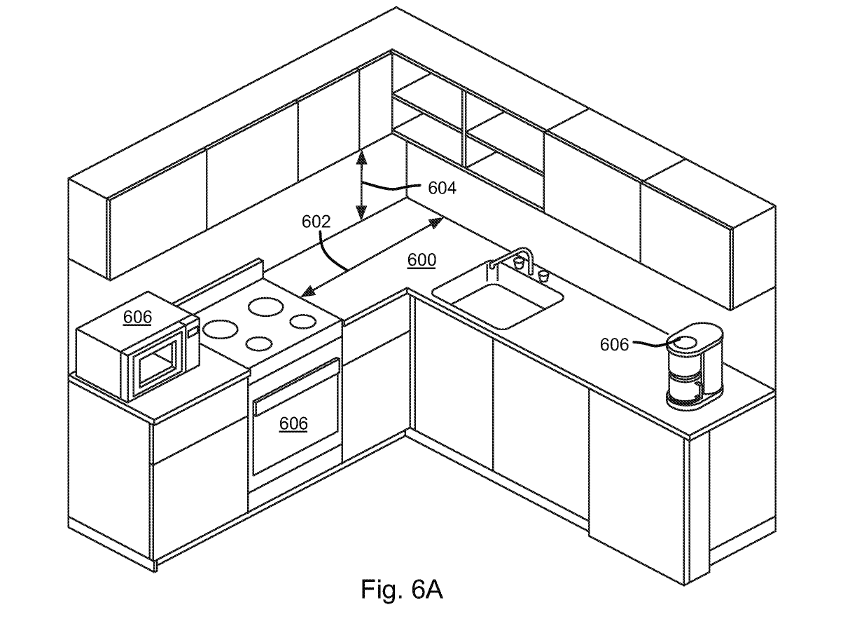

The design engine 114 may include a style module 120c. The style module 120c receives style inputs from a user and selects products and treatments consistent with the style inputs received and the model of the space obtained by the model module 120a. The operation of the style module 120c is described below with respect to FIGS. 4 and 5.

In some embodiments, the design engine 118 may include a rendering module 120d. The rendering module 120d enables the modification and viewing of a model, including a model modified to include products and treatments selected by the style module 120b.

In some embodiments, an interface module 120e may provide an interface for receiving user inputs, e.g. style inputs and design choices discussed below, and for interfacing with an output device, such as a 3D printer.

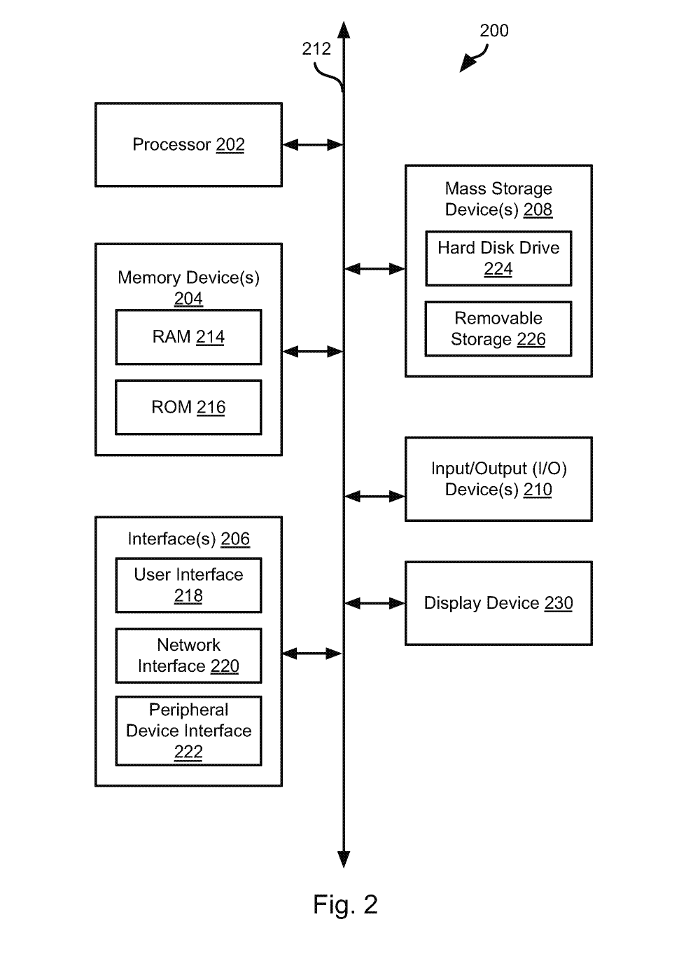

FIG. 2 is a block diagram illustrating an example computing device 200. Computing device 200 may be used to perform various procedures, such as those discussed herein. The server system 102 may have some or all of the attributes of the computing device 200. Computing device 200 can function as a server, a client, or any other computing entity. Computing device can perform various monitoring functions as discussed herein, and can execute one or more application programs, such as the application programs described herein. Computing device 200 can be any of a wide variety of computing devices, such as a desktop computer, a notebook computer, a server computer, a handheld computer, a tablet computer and the like. A server system 102 may include one or more computing devices 200 each including one or more processors.

Computing device 200 includes one or more processor(s) 202, one or more memory device(s) 204, one or more interface(s) 206, one or more mass storage device(s) 208, one or more Input/Output (I/0) device(s) 210, and a display device 230 all of which are coupled to a bus 212. Processor(s) 202 include one or more processors or controllers that execute instructions stored in memory device(s) 204 and/or mass storage device(s) 208. Processor(s) 202 may also include various types of computer-readable media, such as cache memory.

Memory device(s) 204 include various computer-readable media, such as volatile memory (e.g., random access memory (RAM) 214) and/or nonvolatile memory (e.g., read-only memory (ROM) 216). Memory device(s) 204 may also include rewritable ROM, such as Flash memory.

Mass storage device(s) 208 include various computer readable media, such as magnetic tapes, magnetic disks, optical disks, solid-state memory (e.g., Flash memory), and so forth. As shown in FIG. 2, a particular mass storage device is a hard disk drive 224. Various drives may also be included in mass storage device(s) 208 to enable reading from and/or writing to the various computer readable media. Mass storage device(s) 208 include removable media 226 and/or non-removable media.

I/O device(s) 210 include various devices that allow data and/or other information to be input to or retrieved from computing device 200. Example I/O device(s) 210 include cursor control devices, keyboards, keypads, microphones, monitors or other display devices, speakers, printers, network interface cards, modems, lenses, CCDs or other image capture devices, and the like.

Display device 230 includes any type of device capable of displaying information to one or more users of computing device 200. Examples of display device 230 include a monitor, display terminal, video projection device, and the like.

Interface(s) 206 include various interfaces that allow computing device 200 to interact with other systems, devices, or computing environments. Example interface(s) 206 include any number of different network interfaces 220, such as interfaces to local area networks (LANs), wide area networks (WANs), wireless networks, and the Internet. Other interface(s) include user interface 218 and peripheral device interface 222. The interface(s) 206 may also include one or more peripheral interfaces such as interfaces for printers, pointing devices (mice, track pad, etc.), keyboards, and the like.

Bus 212 allows processor(s) 202, memory device(s) 204, interface(s) 206, mass storage device(s) 208, I/O device(s) 210, and display device 230 to communicate with one another, as well as other devices or components coupled to bus 212. Bus 212 represents one or more of several types of bus structures, such as a system bus, PCI bus, IEEE 1394 bus, USB bus, and so forth.

For purposes of illustration, programs and other executable program components are shown herein as discrete blocks, although it is understood that such programs and components may reside at various times in different storage components of computing device 200, and are executed by processor(s) 202. Alternatively, the systems and procedures described herein can be implemented in hardware, or a combination of hardware, software, and/or firmware. For example, one or more application specific integrated circuits (ASICs) can be programmed to carry out one or more of the systems and procedures described herein.

Referring to FIG. 3, the illustrated method 300 may be executed by a server system 102 in combination with sensors 104 in order to characterize a space. The method 300 may include performing 302 a 3D scan of a space. Performing 302 a 3D scan may include obtaining both a point cloud of measurements of the space as well as images of the space. The point cloud and images may then be combined to obtain a full-color model of the space. In some embodiments, a full color model is obtained exclusively using images rather than using a point cloud from a laser scanner.

The method 300 may further include performing acoustic measurements 304. This may include emitting a sound while recording sound within the space in order to measure the acoustic properties of the space. The method 300 may include performing 306 thermal measurements using a thermal imaging camera to determine the temperature of surfaces of the room. The method 300 may include determining 308 an orientation of the space. This may include using a GPS receiver to measure the geographic bounds of the room. A compass may also be used to determine the direction in which various walls of the space face.

The method 300 may include identifying 310 features in the space, including doors, windows, counters, pieces of furniture, and the like. Windows may be identified based on their geometry: a vertical planar surface that is offset horizontally from a surrounding planar surface. Doors may be identified in a similar manner: a rectangular gap in a vertical planar surface. Counters and tables may be identified as horizontal planar surfaces vertically offset above a horizontal planar surface representing a floor. Features may also be identified 310 manually. For example, a user may select a feature and specify what it is (window, table, dresser, etc.).

The method 300 may further include obtaining 312 weather information for the location of the space. This may include seasonal information e.g. temperature variation, days of sunshine, the angle of incidence of sunlight on the space, rainfall, snowfall, and other weather data.

The method 300 may include determining 314 environmental loads for the space based on the weather data as well as the orientation of the space and the location of windows and doors. In particular, the direction a window is facing in combination with the sunlight incident on the space to determine an amount of UV radiation incident on the window. Likewise, a heat load due to sunlight and a cooling light due to low exterior temperatures may also be calculated at step 314.

In some embodiments, lighting of the space may also be measured 316. For example, at one or more points in time, the amount of lumens in the space with lights turned on may be measured.

Referring to FIG. 4, the illustrated method 400 may be executed by the server system 102 in order to select products for use in the space evaluated using the method 300. The method 400 may include an electronic survey conducted of a user to determine a user's preferences. In particular, the method 400 may include receiving 402 a user's style preference. This may include a designation of a particular style (modern, industrial, southwest, traditional Japanese, etc.). Step 402 may further include receiving a selection of a color or palette of preferred colors.

In some embodiments, receiving 402 a style preference may include specifying how the user would like to have furniture arranged. For example, a user may specify “loose,” meaning furniture is spaced part and a room is left open. A user may specify “tight,” meaning more use of space with furniture is desired. These preferences may then be used to select and place furniture in order to meet a client's expectations. The definition of “loose” and “tight” may be defined by software. For example “loose” may require that X percent of floor space be unoccupied whereas “tight” may permit Y percent of floor space to be occupied, where Y is greater than X. Accordingly, for the “loose” preference, smaller items and/or fewer items of furniture may be selected as compared to the “tight” preference. In some embodiments, receiving 402 a style preference may include receiving a design philosophy (e.g. Feng Shui) or the like. Accordingly, the server system may select products and arrange products according to this design philosophy.

The method 400 may include receiving or determining 404 the family make-up of the user. In particular, the age and number of children and the size and type of any pets may be received. The presence of children may also be determined from scan data, e.g. the presence of toys or by analyzing pictures of the user's family.

The method 400 may further include receiving or determining 406 a user's schedule. For example, if the user works at night, then this may be noted for use in selected products (e.g. blackout curtains) suitable for someone who sleeps during the day. Likewise someone who works from home may have suitable office products recommended.

The method 400 may include receiving 408 the measurement data obtained from execution of the method 300. Using the information obtained at steps 402-408, products may be selected that are consistent therewith. The process by which products are selected is described below with respect to FIG. 5. Once products have been selected by a user, models of the selected products are added 412 to the model of the space obtained from step 302. Where the product is a treatment (e.g. paint) or a custom sized component (e.g. carpet or curtains), the model may be updated to include a surface with the treatment (e.g. with a wall having an appropriate paint color) or with an appropriately sized product in an appropriate place (e.g. curtains of an appropriate size in the windows).

The placement of products within the model may be determined according to the measured properties of the space and the properties of the products: insulating products placed on surfaces determined to have a high heating or cooling load, UV tolerant products placed where sunlight shines, TVs may be placed out of sunlight, lamps may be placed to avoid creating glare on the TV, and the like.

The method 400 may then include rendering 414 the combined model on a display device. For example, a virtual model of the space may be navigated by the user such that a user may virtually move through the space such that the rendering is modified to show the space from the user's current point of view. Rendering the combined model may include rendering the model using a virtual reality head set. In some embodiments, the combined model may be three-dimensionally printed. The combined model may also be stored for later retrieval for further modification or rendering.

In some embodiments, the combined model may be analyzed for its thermal, acoustic, lighting or other properties. In particular, using the measured properties of the space and recorded properties for the products added, the thermal, acoustic, or lighting properties of the room may be analyzed and compared to the properties of the room as measured to determine whether the products achieve an improvement.

FIG. 5 illustrates a method 500 that may be executed by the server system 102 to select candidate products for a space. The method 500 may include identifying 502 products that satisfy size constraints. As noted above, the space is three-dimensionally scanned to obtain a model of the room. The dimensions of potential products may be analyzed to identify 502 products that will fit in the space.

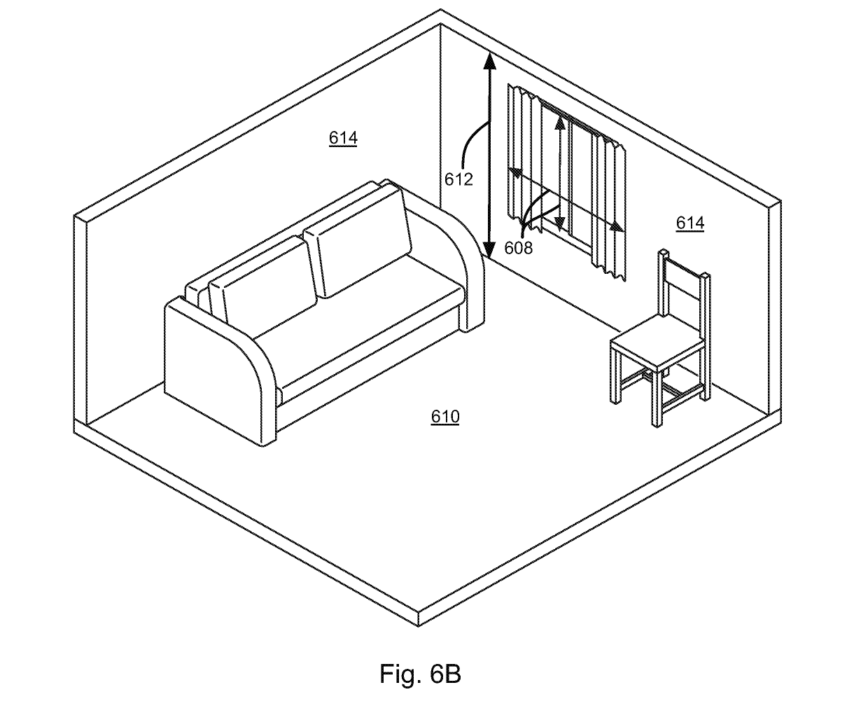

For example, referring to FIG. 6A, the illustrated counter 600 may be selected as the place for an appliance. The horizontal extent 602 of the counter 600 and a vertical clearance 604 above the counter may be determined from the model as well as the locations of other appliances or obstructions 606. Accordingly, an appliance, e.g. toaster oven, coffee maker, etc. selected for the space may be selected as not exceeding the size of the counter.

In another example, referring to FIG. 6B, the dimensions 608 of windows may be determined from the model and appropriately sized curtains may be defined that fit within the window. Likewise, the area of a floor 610 not occupied by furniture may be determined from the model. The floor-to-ceiling height 612 of the space and available wall area 614 of the space may be determined and furniture and decorations may be identified at step 502 that will fit within the constraints of the floor area 610, ceiling height 612, and wall area 614.

Of course, some products, such as paint, may be applied to area regardless of size. Accordingly, products that are not subject to space constraints may be included in the set of products identified at step 502 for subsequent analysis according to the method 500.

Steps 504-514 illustrate various filtering steps whereby products satisfying the constraints of step 502 may be further limited based on other criteria. The steps 504-514 may be performed in any order and some or all may be omitted. An output of those of the steps 504-514 that are executed may be a subset of products that are then presented to the user for selection at step 516. The product set analyzed in each step 504-514 may include a set of products remaining after a filtering step of a preceding step. In some embodiments, a product may not be implicated by a filtering step and therefore may pass through to the next filtering step.

The method 500 may include identifying 504 a first subset of products satisfying style constraints. This may include identifying products having colors belonging to the color palette selected at step 402 and being consistent with the style selected at step 402. This may include evaluating the color data 112f and style data 112g of product records and eliminating those products that do not have color data 112f corresponding to the selected color palette or that have style data that is inconsistent with the style specified at step 402.

The method 500 may include identifying 506 a second subset of products satisfying thermal constraints. Some products, such as curtains may provide insulative properties and therefore be appropriate for a space with a high heat load or high cooling load. Likewise, carpeting may be lighter or more insulative. Accordingly, identifying 506 the second set of products may include identifying products that have thermal properties listed in the product record 110 thereof and removing those that are inconsistent with the heating or cooling load on a space as determined at step 314.

The products of the second subset may be both selected and arranged according to thermal properties thereof. For example, if thermal measurement indicates a large amount of heat entering a room, items may be selected to insulate therefrom.

Likewise elements such as a heater for cold areas and fans for hot areas may be recommended. Heat generating products may be avoided where thermal measurements indicate that a room is too hot. For example, LEDs may be used instead of Halogen or incandescent. For walls having low insulation, heavier curtains could be used or other more insulating decorations. A cooking area may need to be cooler such that heat-generating components are not selected or are placed away from the cooking area.

The method 500 may include identifying 508 a third subset of products satisfying acoustic constraints. For example, where the acoustic measurements of step 304 indicates that a room has a first amount of acoustic damping, products with acoustic data in the product records 110 thereof that will raise or lower that acoustic damping to a specified target level may be selected at step 508.

The method 500 may include identifying 510 a fourth subset of products that satisfy family and pet constraints of a user. For example, a user is found to have children of a certain age or pets of a certain size and type, then products that are inconsistent therewith may be removed with the remaining products being the fourth subset of products. For example, where a user has a four year old child, a product having child age data 112e indicating appropriateness for use around children five years old and older, then that product may be omitted from the fourth subset. Likewise, a product that includes an entry indicating unsuitability for use around dogs or cats may be omitted from the fourth subset if the user has a dog or a cat.

The method 500 may include identifying 512 a fifth subset of products that satisfy environmental constraints. This may include identifying products that have, for example, UV properties 112c consistent with UV exposure of the space as determined at step 314.

The method 500 may include identifying 514 a sixth subset of products satisfying lighting constraints. For example, according to the lighting measurement of step 316, the space may be determined to be too dark (e.g. having a lumen measurement below a threshold). Accordingly, products that may brighten the room by having reflective surfaces or light colors may be selected. Where the space is determine to be too bright (e.g. having a lumen measurement above a threshold), products may be identified for the sixth set that have matte surfaces and darker colors.

The method 500 may include presenting 516 products to the user this may include presenting a set of products satisfying all of the constraints of some or all of steps 502-514. The products may be presented as a listing (e.g. webpage) including images of the products. The products may be presented in a combined model including models of the products applied to the space (see steps 412-414). The user may then provide instructions to accept products, remove products, substitute products with other products, or rearrange products in the space.

In some embodiments, upon selecting a product, a user may be presented with a set of products compatible with that product from among the set of products filtered according to steps 502-514. In particular, upon selecting a product of particular color, products of a compatible color palette may be presented. Likewise, where a product of a particular size is selected for a particular place, products sized to fit within remaining space may be presented and those that are no longer compatible may be omitted.

The method 500 may include receiving 518 product selections. The as noted above a user may select a product using a pointing device or other means. The products selected may then be processed according to steps 412-414 as described above. The selected products may also be ordered and shipping thereof to the customer may be invoked. The selected products may be presented as a shopping list for the customer to print out or order online.

As is readily apparent from the foregoing description, the systems and methods disclosed herein facilitate the choosing of home decorations or accessory items such as curtains, blankets, table settings, paintings, lamps/lighting, etc.

For example, using measurements of windows from the 3D mode, the size of curtain needed may be determined. Likewise, curtains may be selected that satisfy the various constraints discussed herein. For example, curtains may be selected based on the amount of sun the room will receive during various times of the day, the type of room (bedroom versus living room), wall insulation, window thermal transfer, acoustics, season, geographic zone, customer work schedule (e.g. working nights or days), family makeup, amount of light preferred, a desired temperature, and room lighting. The curtains may also be selected as corresponding to a specified color palette, texture, styles, or other criteria. The curtains satisfying the measured properties and received input from the customer may then be selected and added to the combined model to enable visualization thereof. Other products for use with the curtains could also be suggested based on the dimensions and other measured properties of the room, such as a curtain rod, valance, tie-back, or the like.

In another example, shorter curtains may be suggested to a customer that has cats. Blackout curtains may be recommended for a customer that works nights. Thicker curtains may be recommended for colder climates. Strong and non-flammable curtains may be recommended for a user with small children.

For another example, the system disclosed herein may assist in choosing and arranging tableware and kitchen/counter accessories such as plates, glasses, silverware to match a table, service size, design scheme, etc. In particular, an amount of available space on a table or counter may be determined from the model of the space and products identified that fit as well as satisfy color and style constraints of the user.

In addition to recommending products, services for installing recommended products may be provided. For example, for a product that may require expert installation, a list of contractors providing such installation may be linked to a listing of the product. The combined model may be shared with contractors to facilitate the providing of estimates and performing the installation.

Inasmuch as a 3D model of the space is obtained, the texture of a surface may be determined from the 3D model. Where a product selected at step 410 is paint, the amount of paint require to coat the surface may be determined from both the lateral and vertical (or horizontal) extent of the surface as well as its texture.

In a similar manner, where a product selected is a tile or other covering, the number of tiles or amount of material for other types of covering may be determined from the extent of the area to be covered as indicated by the 3D model. For items like tiles, a layout of the tiles, including where to place partial tiles may be automatically determined for the size and shape of the floor and the location of doorways.

In some embodiments, the measurement of texture using the 3D model may be used to identify outdated treatments such as popcorn ceilings, artificial wood paneling and the like. Accordingly, in response to identifying such treatments in the model, the server system may recommend an upgrade treatment for the outdated treatment. The server system may identify currently popular upgrades from purchases of other customer's in geographic proximity to the space and/or friends (e.g. on a social network) of the user. In some embodiments, a user may specify an age of the home and upgrades may be selected based on an assumption as to what upgrades may be needed based on the age of the home.

In some embodiments, the server system 102 may provide step-by-step directions in order to position the products in the room. In particular, an ordering of steps required to achieve the final configuration without collisions and minimizing movements of furniture etc. may be determined. In particular, using models of the products, movements of the products into positions may be modeled and orderings tested until one is found that avoids collisions and has fewer rearrangements as compared to other possible orderings of placement.

The present invention may be embodied in other specific forms without departing from its spirit or essential characteristics. The described embodiments are to be considered in all respects only as illustrative, and not restrictive. The scope of the invention is, therefore, indicated by the appended claims, rather than by the foregoing description. All changes which come within the meaning and range of equivalency of the claims are to be embraced within their scope.

1. A method comprising:
scanning, by a computer system, an interior space;
generating, by the computer, an interior space model according to the scanning of the interior space;
receiving, by the computer system, one or more style inputs from a user;
identifying, by the computer system, a set of products from a product database, each product in the set of products having size attributes compatible with the interior space and style attributes corresponding to the one or more style inputs;
selecting, by the computer system, for each product of the set of products a selected location in the interior space for the each product;
generating, by the computer system, a combined model including the interior space model and the set of products, each product of the set of products located within the interior space model at a the selected location in the interior space for the each product;
outputting, by the computer system, to a display device, a rendering of the combined model.

2. The method of claim 1, further comprising:
receiving, by the computer system, one or more family attributes of the user;
wherein identifying the set of products from the product database comprises identifying the set of products as having metadata corresponding to the one or more family attributes of the user.

3. The method of claim 1, further comprising:
testing, by the computer system, acoustic room properties of the interior space; and
wherein identifying the set of products from the product database comprises identifying the set of products as having metadata indicating acoustic product properties complementing the acoustic room properties.

4. The method of claim 1, further comprising:
retrieving, by the computer system, a geographic location and orientation of the interior space;
retrieving, by the computer system, weather information for the geographic location;
wherein identifying the set of products from the product database comprises identifying the set of products as having metadata indicating compatibility with weather conditions in the interior space in accordance with the orientation of the interior space and the weather information.

5. The method of claim 4, wherein selecting for each product of the set of products the selected location in the interior space for the each product comprises selecting the selected location for the each product according to compatibility of the each product to sunlight incident on the selected location as indicated by the weather information and orientation of the interior space.

6. The method of claim 1, further comprising:
testing, by the computer system, thermal room properties of the interior space; and
wherein identifying the set of products from the product database comprises identifying the set of products as having metadata indicating thermal product properties complementing the thermal room properties.

7. The method of claim 1, wherein identifying the set of products from the product database, each product in the set of products having size attributes compatible with the interior space and style attributes corresponding to the one or more style inputs comprises:
identifying, by the computer system, a feature in the interior space;
identifying, by the computer system, a fitted product in the product database sized to fit the feature; and
adding, by the computer system, the fitted product to the set of products.

8. The method of claim 7, wherein the feature is a window and the fitted product is blinds for the window.

9. The method of claim 1, further comprising:
identifying, by the computer system, a feature in the interior space;
identifying, by the computer system, an upgrade to the feature;
adding, by the computer system, the upgrade to the set of products.

10. The method of claim 1, wherein the one or more style inputs from a user comprises receiving a color palette from the user and wherein the set of products include colors from the color palette.

11. A system comprising one or more processing devices and one or more memory devices coupled to the one or more processing devices, the one or more memory devices storing executable code effective to cause the one or more processing devices to:
scan, using a scanning device, an interior space;
generate an interior space model according to the scanning of the interior space;
receive one or more style inputs from a user;
identify a set of products from a product database, each product in the set of products having size attributes compatible with the interior space and style attributes corresponding to the one or more style inputs;
select for each product of the set of products a selected location in the interior space for the each product;
generate a combined model including the interior space model and the set of products, each product of the set of products located within the interior space model at a the selected location in the interior space for the each product;
output, to a display device, a rendering of the combined model.

12. The system of claim 11, wherein the executable code is further effective to cause the one or more processing devices to:
receive one or more family attributes of the user;
identify the set of products from the product database by identifying the set of products as having metadata corresponding to the one or more family attributes of the user.

13. The system of claim 11, wherein the executable code is further effective to cause the one or more processing devices to:
test acoustic room properties of the interior space; and
identify the set of products from the product database by identifying the set of products as having metadata indicating acoustic product properties complementing the acoustic room properties.

14. The system of claim 11, wherein the executable code is further effective to cause the one or more processing devices to:
retrieve a geographic location and orientation of the interior space;
retrieve weather information for the geographic location;
identify the set of products from the product database by identifying the set of products as having metadata indicating compatibility with weather conditions in the interior space in accordance with the orientation of the interior space and the weather information.

15. The system of claim 14, wherein the executable code is further effective to cause the one or more processing devices to:
select for each product of the set of products the selected location in the interior space for the each product by selecting the selected location for the each product according to compatibility of the each product to sunlight incident on the selected location as indicated by the weather information and orientation of the interior space.

16. The system of claim 11, wherein the executable code is further effective to cause the one or more processing devices to:
test thermal room properties of the interior space; and
identify the set of products from the product database by identifying the set of products as having metadata indicating thermal product properties complementing the thermal room properties.

17. The system of claim 11, wherein the executable code is further effective to cause the one or more processing devices to identify the set of products from the product database, each product in the set of products having size attributes compatible with the interior space and style attributes corresponding to the one or more style inputs by:
identifying a feature in the interior space;
identifying a fitted product in the product database sized to fit the feature; and
adding the fitted product to the set of products.

18. The system of claim 17, wherein the feature is a window and the fitted product is blinds for the window.

19. The system of claim 11, wherein the executable code is further effective to cause the one or more processing devices to:
identify a feature in the interior space;
identify an upgrade to the feature;
add the upgrade to the set of products.

20. The system of claim 11, wherein the one or more style inputs from a user include a color palette and the set of products include colors from the color palette.
